(19) United States
(12) Patent Application Publication
(10) Pub. No.: US 2025/0378889 A1
(43) Pub. Date: Dec. 11, 2025

(54) POWER RAIL DESIGN FOR A MEMORY SYSTEM

(71) Applicant: Micron Technology, Inc., Boise, ID (US)

(72) Inventors: Liang Yu, Boise, ID (US); Dustin L. Holloway, Boise, ID (US); Jonathan S. Parry, Boise, ID (US)

(21) Appl. No.: 19/222,869

(22) Filed: May 29, 2025

Related U.S. Application Data
(60) Provisional application No. 63/658,708, filed on Jun. 11, 2024.

(51) Int. Cl. G11C 16/30; G11C 16/04

(52) U.S. Cl. CPC G11C 16/30; G11C 16/0483

(57) ABSTRACT

Methods, systems, and devices for power rail design for a memory system are described. A host system may power a memory system using a first power rail, a second power rail, and a third power rail. The first power rail may be coupled with the memory device and configured to power one or more first components of the memory device at a first voltage level. The second power rail may be coupled with the memory device and configured to power one or more second components of the memory device at a second voltage level. The third power rail may be coupled with the memory system controller and configured to power one or more third components of the memory system controller at a third voltage level.

### CROSS REFERENCE

The present application for patent claims priority to U.S. Patent Application No. 63/658,708 by Yu et al., entitled “POWER RAIL DESIGN FOR A MEMORY SYSTEM,” filed Jun. 11, 2024, which is assigned to the assignee hereof, and which is expressly incorporated by reference in its entirety herein.

### TECHNICAL FIELD

The following relates to one or more systems for memory, including power rail design for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports power rail design for a memory system in accordance with examples as disclosed herein.

FIGS. 2A and 2B illustrate examples of a system that support power rail design for a memory system in accordance with examples as disclosed herein.

FIG. 3 shows an example of a system that supports power rail design for a memory system in accordance with examples as disclosed herein.

FIG. 4 shows an example of a system that supports power rail design for a memory system in accordance with examples as disclosed herein.

FIG. 5 shows an example of a system that supports power rail design for a memory system in accordance with examples as disclosed herein.

### DETAILED DESCRIPTION

In some examples, a memory system may be coupled with a host system. The host system may support various functions of the memory system, one of which may include supplying power to the memory system. The host system may supply power to the memory system using a first power rail (e.g., Vcc) and a second power rail (e.g., Vccq). A power rail may be coupled with a power supply of the host system, and may be defined as a voltage source from which a specific component of the memory system may be able to draw power. The first power rail may have first voltage level (e.g., of 2.5 volts) and may supply power to one or more memory devices of the memory system. The second power rail may have a second voltage level (e.g., of 1.2 volts) and may supply power to a controller of the memory system as well as the one or more memory devices of the memory system. In some examples, a third voltage level used to power a core of the controller may be less than the second voltage level of the second power rail. For example, the third voltage level may be equal to 0.75 volts and the second voltage level may be equal to 1.2 volts. As such, the first power rail may be coupled with a voltage regulator (e.g., a low dropout regulator (LDO)) within the controller which may decrease a voltage supplied to the core from the second voltage level to the third voltage level. However, decreasing the second voltage level in such a way may result in a unnecessary loss in energy and an overall increase in power consumption. Therefore, a new power rail design for the memory system may be desirable to decrease unnecessary energy loss, among other challenges.

As described herein, the host system may supply power to the memory system using multiple power rails, such as a first power rail, a second power rail, and a third power rail. The first power rail (e.g., Vcc) may be coupled with the one or more memory devices of the memory system and may be configured to power one or more first components of the one or more memory devices at a first voltage level (e.g., 2.0 volts). The second power rail (e.g., Vccq) may be coupled with the one or more memory devices and may be configured to power one or more second components of the one or more memory devices at a second voltage level (e.g., 1.2 volts). The third power rail (e.g., VccqX) may be coupled with the controller and may be configured to power one or more third components (e.g., the core) of the controller at another (e.g., a fourth) voltage level.

As opposed to other different methods, the voltage level of the power rail coupled with the core of the controller (e.g., the fourth voltage level of the third power rail) may be equal to or within a threshold value of a third voltage level (e.g., 0.75 volts). For example, the fourth voltage level may be equal to 0.75 volts or 1 volt, among other values. In this case, because the difference between the third voltage level and the fourth voltage level is smaller than the difference between the third voltage level and the second voltage level, less energy may be lost during operation, among other advantages.

In addition to applicability in memory systems as described herein, the multiple power rail design described herein may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by decreasing power consumption of the memory system, which may extend the life of electronic devices and thereby reducing electronic waste, among other benefits. Features of the disclosure are illustrated and described in the context of systems, devices, and circuits.

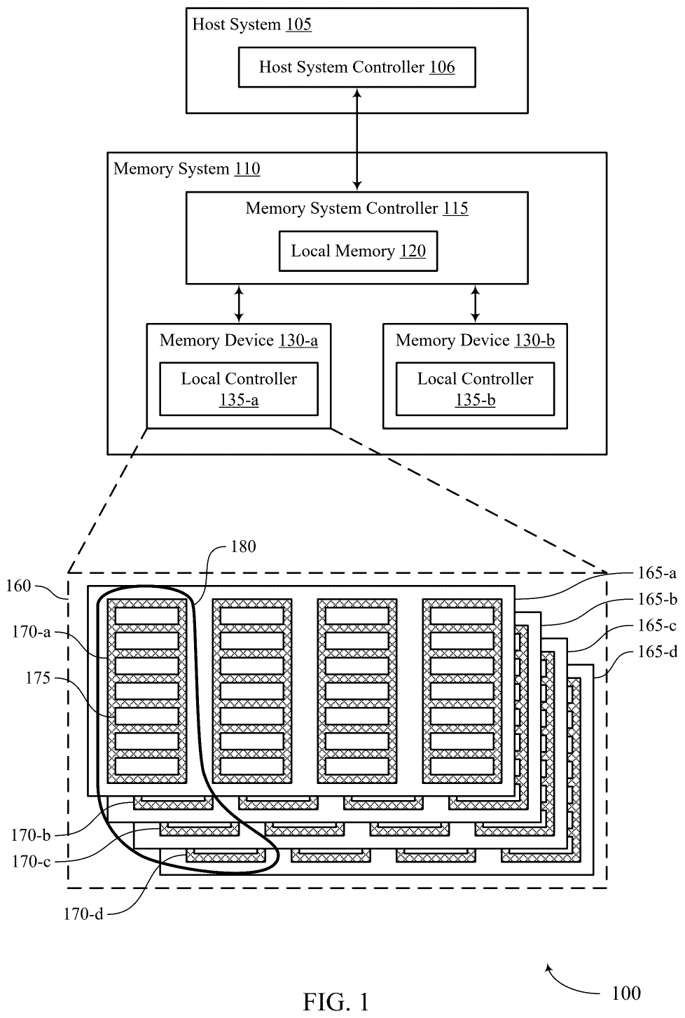

FIG. 1 shows an example of a system 100 that supports power rail design for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support power rail design for a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

As described herein, the host system 105 may power the memory system 110 using a first power rail, a second power rail, and a third power rail. In some examples, the first power rail may be coupled with the memory device 130 and configured to power one or more first components of the memory device 130 at a first voltage level. The second power rail may be coupled with the memory device 130 and configured to power one or more second components of the memory device 130 at a second voltage level. The third power rail may be coupled with the memory system controller 115 and configured to power one or more third components of the memory system controller 115 at a third voltage. In some examples, the one or more third components of the memory system controller 115 may include a core of the memory system controller 115 and the third voltage level may be equal to or within a threshold value of a voltage level (e.g., 0.75 volts) that the memory system controller 115 may utilize to power the core. Using the rail design as described here may reduce a quantity of high current regulators in the memory system 110 which may reduce the overall power consumption of the memory system 110.

The system 100 may include any quantity of non-transitory computer readable media that support power rail design for a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

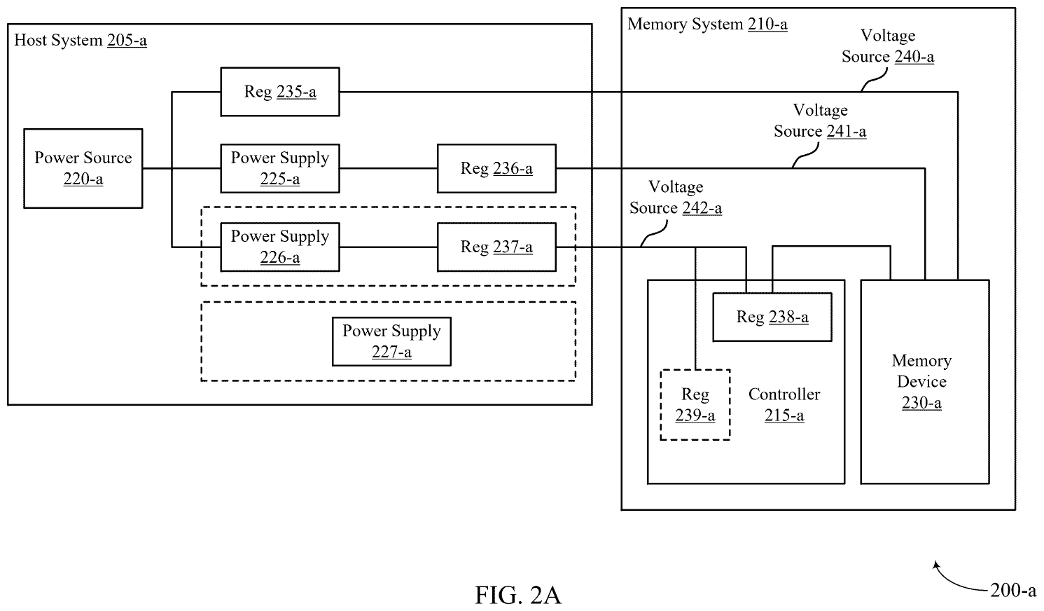

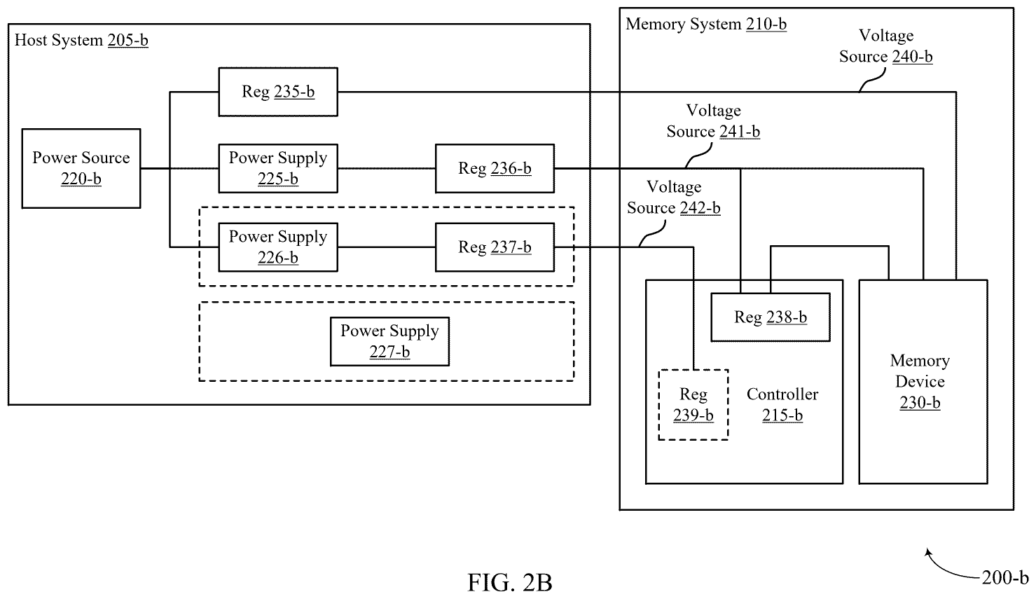

FIGS. 2A and 2B show examples of a system 200 (e.g., a system 200-a and a system 200-b) that supports a power rail design for a memory system in accordance with examples as disclosed herein. In some examples, the systems 200 may support aspects of the system 100. For example, the systems 200 may include a host system 205, a memory system 210, one or more memory devices 230, and one or more controllers 215 which may be examples of a host system 105, a memory system 110, one or more memory devices 130, and one or more memory system controllers 115 as described with reference to FIG. 1, respectively.

As described herein, the host system 205 (e.g., a host system 205-a or a host system 205-b) may supply power to the memory system 210 (e.g., a memory system 210-a or a memory system 210-b) using a three power rail design. As shown in FIGS. 2A and 2B, the host system 205 may include a power source 220 (e.g., a power source 220-a, a power source 220-b, or a battery) that is coupled with a regulator 235 (e.g., a regulator 235-a, a regulator 235-b, or an LDO), a power supply 225 (e.g., a power supply 225-a or a power supply 225-b), and a power supply 226 (e.g., a power supply 226-a or a power supply 226-b). In some examples, a voltage level of the power source 220 may be equal to 3.8 volts.

The regulator 235 may be coupled with a voltage source 240 (e.g., a first power rail) and may be configured to regulate a voltage supplied to the voltage source 240 of the memory system 210 such that the voltage is equal to a first voltage level (e.g., 2.5 volts). The power supply 225 and the power supply 226-a may be examples of switched mode power supplies (SMPSs) and may be coupled with a regulator 236 (e.g., a regulator 236-a, a regulator 236-b, or an LDO) and a regulator 237 (e.g., a regulator 237-a, a regulator 237-b, or an LDO), respectively.

The regulator 236 may be coupled with a voltage source 241 (e.g., a second power rail) and may be configured to regulate a voltage supplied to the voltage source 241 such that the voltage is equal to a second voltage level (e.g., 1.2 volts). The regulator 237 may be coupled with a voltage source 242 (e.g., a third power rail) and may be configured to regulate a voltage supplied to the voltage source 241 such that the voltage is equal to a third voltage level (e.g., 0.5 volts to 1.0 volt). Alternatively, the power supply 226 and the regulator 237 may be replaced with a single power supply 227 (e.g., a power supply 227-a, a power supply 227-b, or an SMPS). In such examples, the power supply 227 may be coupled with the voltage source 242. In some examples, the second voltage level and the third voltage level may be less than the first voltage level and the third voltage level may be less than the second voltage level.

In the example of FIG. 2A, the voltage source 240-a may be coupled with the memory device 230-a and may be configured to power one or more first components of the memory device 230-a at the first voltage level. For example, the voltage source 240-a may power a core of the memory device 230-a. Similarly, the voltage source 241-a may be coupled with the memory device 230-a, but may be configured to power one or more second components of the memory device 230-a at the second voltage level. For example, the voltage source 241-a may power a first data path associated with the memory device 230-a (e.g., a NAND data path).

On the other hand, the voltage source 242-a may be coupled with the controller 215-a and may be configured to power one or more third components of the controller 215-a at the third voltage level. For example, the voltage source 242-a may power a core of the controller 215-a and a second data path associated with the controller 215-a and the memory device 230-a (e.g., an ASIC/NAND ONFI data path). In some examples, the controller 215-a may utilize a fourth voltage level (e.g., 0.75 volts) to power the core and a fifth voltage level (e.g., 0.6 volts) to power the second data path. Optionally, the voltage source 242-a may also power other low voltage domains of the controller 215-a or the memory device 230-a such as a physical layer, low density parity check (LDPC), ODT, etc.

In some cases, the third voltage level may be greater than the fourth voltage level and the fifth voltage level. For example, the third voltage level may be equal to 1.0 volts. In such case, the voltage source 242-a may be coupled with a regulator 239-a (e.g., an LDO) within the controller 215-a and a regulator 238-a (e.g., an LDO) within the controller 215-a. The regulator 239-a may be coupled with the core of the controller 215-a and may be configured to regulate a voltage supplied to the core such that the voltage is equal to the fourth voltage level. The regulator 238-a may be coupled with the second data path and may be configured to regulate a voltage supplied to the second data path such that the voltage is equal to the fifth voltage level.

Alternatively, the third voltage may be equal to the fourth voltage level and greater than the fifth voltage level. For example, the third voltage level may be equal to 0.75 volts. In such case, the voltage source 242-a may be coupled (e.g., directly coupled) with the core of the controller 215-a and the regulator 238-a within the controller 215-a. The regulator 238-a may be coupled with the second data path and may be configured to regulate a voltage supplied to the data second path such that the voltage is equal to the fifth voltage level.

In another example, the voltage source 242-a may not be coupled with the regulator 238-a. Instead, the voltage source 242-a may be coupled with the memory device 230-a and may be configured to power the second data path at the third voltage level.

In the example of FIG. 2B, the voltage source 240-b may be coupled with the memory device 230-b and may be configured to power one or more first components of the memory device 230-b at the first voltage level. For example, the voltage source 240-b may power a core of the memory device 230-b. Similarly, the voltage source 241-b may be coupled with the memory device 230-b, but may be configured to power one or more second components of the memory device 230-b at the second voltage level. For example, the voltage source 241-b may power a first data path associated with the memory device 230-b (e.g., a NAND ONFI data path). Further, the voltage source 241-b may be coupled with a regulator 238-b within the controller 215-b. The regulator 238-b may be coupled with a second data path between the memory device 230-b and the controller 215-b (e.g., a NAND/ASIC ONFI path) and may be configured to regulate a voltage supplied to the second data path such that the voltage is equal to the fifth voltage level (e.g., 0.6 volts).

The voltage source 242-b, on the other hand, may be coupled with the controller 215-b and may be configured to power one or more third components of the controller 215-b at the third voltage level. For example, the voltage source 242-b may power a core of the controller 215. In some examples, the controller 215-b may utilize a fourth voltage level (e.g., 0.75 volts) to power the core.

In some examples, the third voltage may be greater than the fourth voltage. For example, the third voltage may be equal to 1.0 volts. In such case, the voltage source 242-b may be coupled with a regulator 239-b within the controller 215-b. The regulator 239-b may be coupled with the core and may be configured to regulate a voltage supplied to the core such that the voltage is equal to the fourth voltage level. Alternatively, the third voltage may be equal to the fourth voltage. For example, the third voltage may be equal to 0.75 volts. In such case, the voltage source 242-b may be coupled (e.g., directly coupled) with the core of the controller 215-b.

By incorporating a voltage source 242 (e.g., third power rail) into the memory system 210, power consumption at the memory system 210 may be lowered if compared to other designs. The voltage source 242 may have a third voltage level which is equal to or within a threshold value of a voltage level used by the controller 215 to power the core or the second data path. This may result in less current being pulled by regulators (e.g., the regulator 238 or the regulator 239) of the controller 215 which may effectively lower the overall power consumption of the memory system 210.

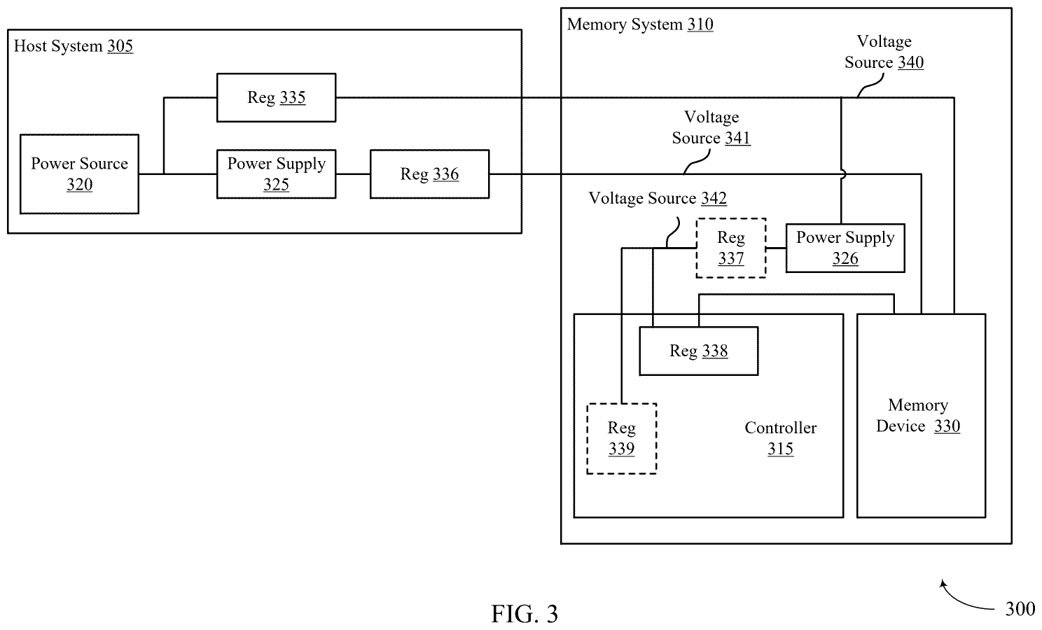

FIG. 3 shows an example of a system 300 that supports a power rail design for a memory system in accordance with examples as disclosed herein. In some examples, the system 300 may support aspects of the system 100 and the system 200. For example, the system 300 may include a host system 305, a memory system 310, one or more memory devices 330, and one or more controllers 315 which may be examples of a host system 105, a memory system 110, one or more memory device 130, and one or more memory system controllers 115 as described with reference to FIG. 1, respectively.

As described herein, the host system 305 may supply power to the memory system 310 using a three power rail design. As shown in FIG. 3, the host system 305 may include a power source 320 (e.g., a battery) that is coupled with a regulator 335 (e.g., an LDO) and a power supply 325. In some examples, a voltage level of the power source 320 may be equal to 3.8 volts. The regulator 335 may be further coupled with a voltage source 340 (e.g., a first power rail) and may be configured to regulate a voltage supplied to the voltage source 340 such that the voltage is equal to a first voltage level (e.g., 2.5 volts).

The power supply 325 may be an example of an SMPS and may be coupled with a regulator 336 (e.g., an LDO). The regulator 336 may be further coupled with a voltage source 341 (e.g., a second power rail) and may be configured to regulate a voltage supplied to the voltage source 341 such that the voltage is equal to a second voltage level (e.g., 1.2 volts).

The voltage source 340 may be coupled with the memory device 330 and may be configured to power one or more first components of the memory device 330 at the first voltage level. For example, the voltage source 340 may power a core of the memory device 330. Further, the voltage source 340 may be coupled with a power supply 326 (e.g., an SMPS) that is located within the memory system 310. In some examples, the power supply 326 may be directly coupled with a voltage source 342 (e.g., a third power rail) and may be configured to supply a target voltage equal to a third voltage level (e.g., 0.75 volts or 1 volt) to the voltage source 342.

Alternatively, the power supply 326 may be potentially coupled with a regulator 337 (e.g., an LDO) of the memory system 310 which is further coupled with the voltage source 342 and may be configured to regulate a voltage supplied to the voltage source 342 such that the voltage is equal to the third voltage level (e.g., 0.75 volts or 1 volt). In some examples, the second voltage level and the third voltage level may be less than the first voltage and the third voltage level may be less than the second voltage level.

The voltage source 341 may be coupled with the memory device 330 and may be configured to power one or more second components of the memory device 330 at the second voltage level. For example, the voltage source 341 may power a first data path associated with the memory device 330 (e.g., a NAND ONFI data path).

Conversely, the voltage source 342 may be coupled with the controller 315 and may be configured to power one or more third components of the controller 315 at the third voltage level. For example, the voltage source 342 may power a core of the controller 315 and a second data path associated with the controller 315 and the memory device 330 (e.g., a ASIC/NAND ONFI data path). In some examples, the controller 315 may utilize a fourth voltage level (e.g., 0.75 volts) to power the core and a fifth voltage level (e.g., 0.6 volts) to power the second data path. Optionally, the voltage source 342 may also power other low voltage domains of the controller 315 or the memory device 330 such as a physical layer, low LDPC, ODT, etc.

In some cases, the third voltage may be greater than the fourth voltage and the fifth voltage. For example, the third voltage may be equal to 1.0 volts. In such case, the voltage source 342 may be coupled with a regulator 339 (e.g., an LDO) within the controller 315 and a regulator 338 (e.g., an LDO) within the controller 315. The regulator 339 may be coupled with the core of the controller 315 and may be configured to regulate a voltage supplied to the core such that the voltage is equal to the fourth voltage level. The regulator 338 may be coupled with the second data path and may be configured to regulate a voltage supplied to the second data path such that the voltage is equal to the fifth voltage level.

Alternatively, the third voltage may be equal to the fourth voltage and greater than the fifth voltage. For example, the third voltage may be equal to 0.75 volts. In such case, the voltage source 342 may be coupled (e.g., directly coupled) with the core of the controller 315 and a regulator 338 within the controller 315. The regulator 338 may be coupled with the second data path and may be configured to regulate a voltage supplied to the data second path such that the voltage is equal to the fifth voltage level. In some examples, the voltage source 342 may not power the second data path (not shown in FIG. 3). Alternatively, the voltage source 341 may be coupled with the regulator 338 and may be configured to power the second data path.

By incorporating a voltage source 342 (e.g., third power rail) into the memory system 310, power consumption at the memory system 310 may be lowered if compared to other designs. The voltage source 342 may have a third voltage level which is equal to or within a threshold value of a voltage level used by the controller 315 to power the core or the second data path. This may result in less current being pulled by regulators (e.g., the regulator 338 or the regulator 339) of the controller 315 which may effectively lower the overall power consumption of the memory system 310.

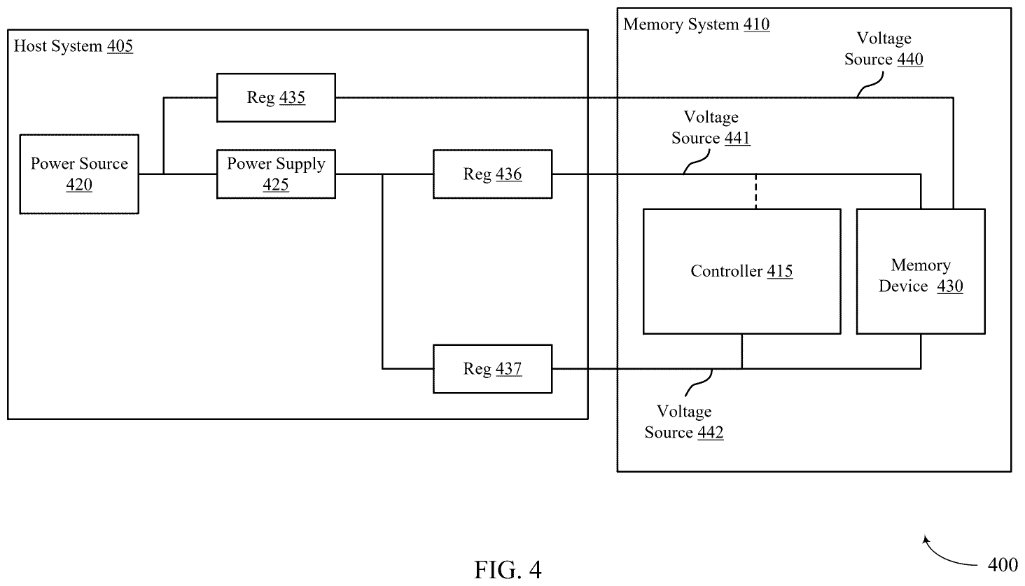

FIG. 4 shows an example of a system 400 that supports a power rail design for a memory system in accordance with examples as disclosed herein. In some examples, the system 400 may support aspects of the system 100, the system 200, and the system 300. For example, the system 400 may include a host system 405, a memory system 410, one or more memory devices 430, and one or more controllers 415 which may be examples of a host system 105, a memory system 110, one or more memory devices 130, and one or more memory system controllers 115 as described with reference to FIG. 1, respectively.

As described herein, the host system 405 may supply power to the memory system 410 using a three power rail design. As shown in FIG. 4, the host system 405 may include a power source 420 (e.g., a battery) that is coupled with a regulator 435 (e.g., an LDO) and a power supply 425. In some examples, a voltage level of the power source 420 may be equal to 3.8 volts. The regulator 435 may be coupled with the voltage source 440 (e.g., a first power rail) and may be configured to regulate a voltage supplied to the voltage source 440 of the memory system 410 such that the voltage is equal to a first voltage level (e.g., 2.5 volts). The power supply 425 may be an example of an SMPS and may be coupled with a regulator 436 (e.g., an LDO) and a regulator 437 (e.g., an LDO).

The regulator 436 may be coupled with a voltage source 441 (e.g., a second power rail) and may be configured to regulate a voltage supplied to the voltage source 441 such that the voltage is equal to a second voltage level (e.g., 1.2 volts). The regulator 437 may be coupled with a voltage source 442 (e.g., a third power rail) and may be configured to regulate a voltage supplied to the voltage source 441 such that the voltage is equal to a third voltage level (e.g., 0.75 volts or 1.0 volt). In some examples, the second voltage level and the third voltage level may be less than the first voltage and the third voltage level may be less than the second voltage level.

The voltage source 440 may be coupled with the memory device 430 and may be configured to power one or more first components of the memory device 430 at the first voltage level. For example, the voltage source 440 may power a core of the memory device 430. Similarly, the voltage source 441 may be coupled with the memory device 430, but may be configured to power one or more second components of the memory device 430 at the second voltage level. For example, the voltage source 441 may power a first data path associated with the memory device 430 (e.g., a NAND ONFI data path). Optionally, the voltage source 441 may be further coupled with the controller 415 and configured to power one or more third components of the controller 415. For example, the voltage source 441 may power a core of the controller 415.

Alternatively or additionally, the voltage source 442 may be coupled with the controller 415 and may be configured to power one or more fourth components of the controller 415 at the third voltage level. For example, the voltage source 442 may power the core of the controller 415 and a second data path associated with the controller 415 and the memory device 430 (e.g., a ASIC/NAND ONFI data path). In some examples, the controller 415 may utilize a fourth voltage level (e.g., 0.75 volts) to power the core and a fifth voltage level (e.g., 0.6 volts) to power the second data path. Optionally, the voltage source 442 may also power other low voltage domains of the controller 415 or the memory device 430 such as a physical layer, LDPC, ODT, etc.

By incorporating a voltage source 442 (e.g., third power rail) into the memory system 410, power consumption at the memory system 410 may be lowered if compared to other designs. The voltage source 442 may have a third voltage level which is equal to or within a threshold value of a voltage level used by the controller 415 to power the core or the second data path. This may result in less current being pulled by regulators of the controller 415 which may effectively lower the overall power consumption of the memory system 410.

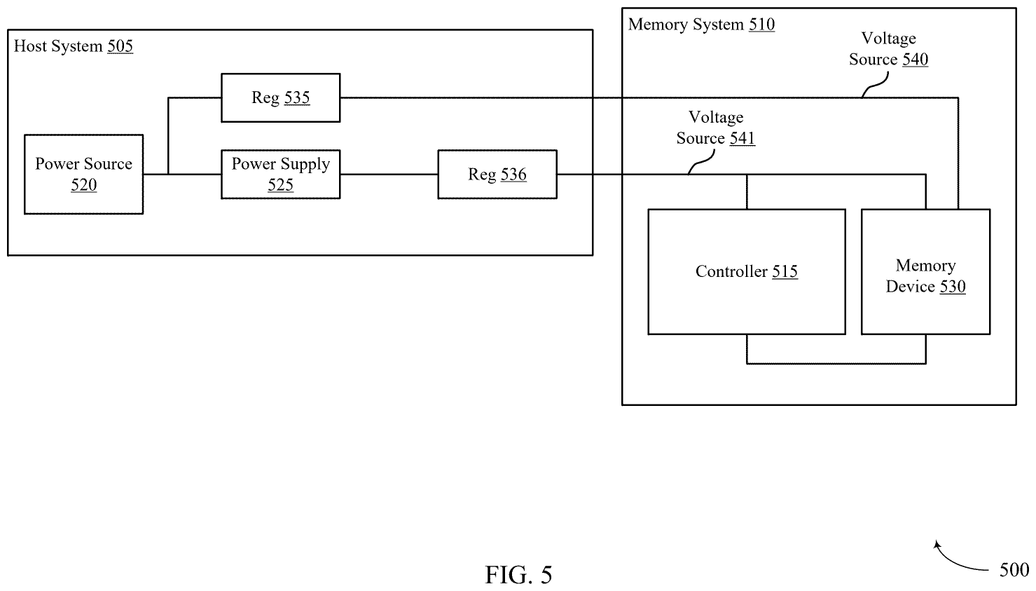

FIG. 5 shows an example of a system 500 that supports a power rail design for a memory system in accordance with examples as disclosed herein. In some examples, the system 500 may support aspects of the system 100, the system 200, the system 300, and the system 400. For example, the system 500 may include a host system 505, a memory system 510, one or more memory devices 530, and one or more controllers 515 which may be examples of a host system 105, a memory system 110, one or more memory devices 130, and one or more memory system controllers 115 as described with reference to FIG. 1, respectively.

As described herein, the host system 505 may supply power to the memory system 510. As shown in FIG. 5, the host system 505 may include a power source 520 (e.g., a battery) that is coupled with a regulator 535 (e.g., an LDO) and a power supply 525. In some examples, a voltage level of the power source 520 may be equal to 3.8 volts. The regulator 535 may be coupled with the voltage source 540 (e.g., a first power rail) and may be configured to regulate a voltage supplied to the voltage source 540 of the memory system 510 such that the voltage is equal to a first voltage level (e.g., 2.5 volts). The power supply 525 may be an example of an SMPS and may be coupled with a regulator 536. The regulator 536 may be coupled with a voltage source 541 (e.g., a second power rail) and may be configured to regulate a voltage supplied to the voltage source 541 such that the voltage is equal to a second voltage level (e.g., 1.2 volts).

The voltage source 540 may be coupled with the memory device 530 and may be configured to power one or more first components of the memory device 530 at the first voltage level. For example, the voltage source 540 may power a core of the memory device 530. Similarly, the voltage source 541 may be coupled with the memory device 530, but may be configured to power one or more second components of the memory device 530 at the second voltage level. For example, the voltage source 541 may power a first data path associated with the memory device 530 (e.g., a NAND ONFI data path). Further, in some examples, the voltage source 541 may be coupled with a first regulator of the controller 515 that is configured to regulate a voltage supplied to a core of the controller 515. In some examples, the voltage supplied to the core may be equal to a third voltage level (e.g., 0.75 volts).

Additionally, or alternatively, the voltage source 541 may be coupled with a second regulator of the controller 515 that is configured to regulate a voltage supplied to a second data path associated with the memory device 530 and the controller 515 (e.g., a NAND/ASIC ONFI data path). In some examples, the voltage supplied to the core may be equal to a fourth voltage level (e.g., 0.75 volts). The second voltage level may be less than the first voltage level, but greater than the third voltage level and the third voltage level.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A memory system, including: one or more controllers; one or more memory devices coupled with at least one of the one or more controllers; a first voltage source coupled with the one or more memory devices, the first voltage source configured to power one or more first components of the one or more memory devices at a first voltage level; a second voltage source coupled with the one or more memory devices, the second voltage source configured to power one or more second components of the one or more memory devices at a second voltage level; and a third voltage source coupled with the one or more controllers, the third voltage source configured to power one or more third components of the one or more controllers at a third voltage level, where the third voltage level is less than the first voltage level and the second voltage level.

Aspect 2: The memory system of aspect 1, where the third voltage source is coupled with a first voltage regulator of the one or more controllers, the first voltage regulator configured to output a signal to the one or more memory devices to power one or more fourth components of the one or more memory devices at a fourth voltage level that is less than the third voltage level.

Aspect 3: The memory system of any of aspects 1 through 2, where the third voltage source is coupled with a second voltage regulator of the one or more controllers, the second voltage regulator configured to output a signal to the one or more controllers to power the one or more third components of the one or more controllers at a fourth voltage level that is less than the third voltage level.

Aspect 4: The memory system of any of aspects 1 through 3, where the second voltage source is coupled with a first voltage regulator of the one or more controllers, the first voltage regulator configured to output a signal to the one or more memory devices to power one or more fourth components of the one or more memory devices at a fourth voltage that is less than the third voltage level.

Aspect 5: The memory system of any of aspects 1 through 4, where the third voltage source is further coupled with the one or more memory devices and further configured to power one or more fourth components of the one or more memory devices at the third voltage level.

Aspect 6: The memory system of any of aspects 1 through 5, where the second voltage source is further coupled with a first voltage regulator of the one or more controllers, the first voltage regulator configured to output a signal to the one or more controllers to power one or more fourth components of the one or more controllers at a fourth voltage that is less than or equal to the third voltage level.

Aspect 7: The memory system of aspect 6, where the one or more fourth components of the one or more controllers include a processing unit of the one or more controllers.

Aspect 8: The memory system of any of aspects 1 through 7, where the one or more third components of the one or more controllers include a processing unit of the one or more controllers.

Aspect 9: The memory system of any of aspects 1 through 8, where the one or more second components of the one or more memory devices include a data path associated with the one or more memory devices.

Aspect 10: The memory system of any of aspects 1 through 9, where the second voltage level is less than the first voltage level.

Aspect 11: The memory system of any of aspects 1 through 10, where the first voltage level is equal to 2.5 volts, the second voltage level is equal to 1.2 volts, and the third voltage level is equal to 0.6 volts, 0.75 volts, or 1 volt.

An apparatus is described. The following provides an overview of aspects of the apparatus as described herein:

Aspect 12: A memory system, including: one or more controllers; one or more memory devices coupled with at least one of the one or more controllers; a first voltage source coupled with the one or more memory devices, the first voltage source configured to power one or more first components of the one or more memory devices at a first voltage level; a power supply coupled with the first voltage source; a second voltage source coupled with the one or more memory devices, the second voltage source configured to power one or more second components of the one or more memory devices at a second voltage level; and a third voltage source coupled with the one or more controllers and the power supply, the third voltage source configured to power one or more third components of the one or more controllers at a third voltage level, where the third voltage level is less than the first voltage level and the second voltage level.

Aspect 13: The memory system of aspect 12, where the third voltage source is coupled with a first voltage regulator of the one or more controllers, the first voltage regulator configured to output a signal to the one or more memory devices to power one or more fourth components of the one or more memory devices at a fourth voltage level that is less than the third voltage level.

Aspect 14: The memory system of any of aspects 12 through 13, where the third voltage source is coupled with a second voltage regulator of the one or more controllers, the second voltage regulator configured to output a signal to the one or more controllers to power the one or more third components of the one or more controllers at a fourth voltage level that is less than the third voltage level.

Aspect 15: The memory system of any of aspects 12 through 14, where the second voltage source is coupled with a first voltage regulator of the one or more controllers, the first voltage regulator configured to output a signal to the one or more memory devices to power one or more fourth components of the one or more memory devices at a fourth voltage that is less than the third voltage level.

Aspect 16: The memory system of any of aspects 12 through 15, where the third voltage source is further coupled with the one or more memory devices and further configured to power one or more fourth components of the one or more memory devices at the third voltage level.

Aspect 17: The memory system of any of aspects 12 through 16, where the second voltage source is further coupled with a first voltage regulator of the one or more controllers, the first voltage regulator configured to output a signal to the one or more controllers to power one or more fourth components of the one or more controllers at a fourth voltage that is less than or equal to the third voltage level.

Aspect 18: The memory system of aspect 17, where the one or more fourth components of the one or more controllers include a processing unit of the one or more controllers.

Aspect 19: The memory system of any of aspects 12 through 18, where the one or more third components of the one or more controllers include a processing unit of the one or more controllers.

Aspect 20: The memory system of any of aspects 12 through 19, where the one or more second components of the one or more memory devices include a data path associated with the one or more memory devices.

Aspect 21: The memory system of any of aspects 12 through 20, where the second voltage level is less than the first voltage level.

Aspect 22: The memory system of any of aspects 12 through 21, where the first voltage level is equal to 2.5 volts, the second voltage level is equal to 1.2 volts, and the third voltage level is equal to 0.6 volts, 0.75 volts, or 1 volt.

An apparatus is described. The following provides an overview of aspects of the apparatus as described herein:

Aspect 23: A memory system, including: one or more controllers; one or more memory devices coupled with at least one of the one or more controllers; a first voltage source coupled with the one or more memory devices, the first voltage source configured to power one or more first components of the one or more memory devices at a first voltage level; and a second voltage source coupled with a first voltage regulator of the one or more controllers, a second voltage regulator of the one or more controllers, and the one or more memory devices, the second voltage source configured to power one or more second components of the one or more controllers and one or more third components of the one or more memory devices at a second voltage level, where the second voltage level is less than the first voltage level.

Aspect 24: The memory system of aspect 23, where the first voltage regulator is configured to output a signal to the one or more controllers to power the one or more second components of the one or more controllers at a third voltage level that is less than the second voltage level.

Aspect 25: The memory system of any of aspects 23 through 24, where the second voltage regulator is configured to output a signal to the one or more memory devices to power one or more fourth components of the one or more memory devices at a third voltage level that is less than the second voltage level.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more controllers;
one or more memory devices coupled with at least one of the one or more controllers;
a first voltage source coupled with the one or more memory devices, the first voltage source configured to power one or more first components of the one or more memory devices at a first voltage level;
a second voltage source coupled with the one or more memory devices, the second voltage source configured to power one or more second components of the one or more memory devices at a second voltage level; and
a third voltage source coupled with the one or more controllers, the third voltage source configured to power one or more third components of the one or more controllers at a third voltage level, wherein the third voltage level is less than the first voltage level and the second voltage level.

2. The memory system of claim 1, wherein the third voltage source is coupled with a first voltage regulator of the one or more controllers, the first voltage regulator configured to output a signal to the one or more memory devices to power one or more fourth components of the one or more memory devices at a fourth voltage level that is less than the third voltage level.

3. The memory system of claim 1, wherein the third voltage source is coupled with a second voltage regulator of the one or more controllers, the second voltage regulator configured to output a signal to the one or more controllers to power the one or more third components of the one or more controllers at a fourth voltage level that is less than the third voltage level.

4. The memory system of claim 1, wherein the second voltage source is coupled with a first voltage regulator of the one or more controllers, the first voltage regulator configured to output a signal to the one or more memory devices to power one or more fourth components of the one or more memory devices at a fourth voltage that is less than the third voltage level.

5. The memory system of claim 1, wherein the third voltage source is further coupled with the one or more memory devices and further configured to power one or more fourth components of the one or more memory devices at the third voltage level.

6. The memory system of claim 1, wherein the second voltage source is further coupled with a first voltage regulator of the one or more controllers, the first voltage regulator configured to output a signal to the one or more controllers to power one or more fourth components of the one or more controllers at a fourth voltage that is less than or equal to the third voltage level.

7. The memory system of claim 6, wherein the one or more fourth components of the one or more controllers comprise a processing unit of the one or more controllers.

8. The memory system of claim 1, wherein the one or more third components of the one or more controllers comprise a processing unit of the one or more controllers.

9. The memory system of claim 1, wherein the one or more second components of the one or more memory devices comprise a data path associated with the one or more memory devices.

10. The memory system of claim 1, wherein the second voltage level is less than the first voltage level.

11. The memory system of claim 1, wherein the first voltage level is equal to 2.5 volts, the second voltage level is equal to 1.2 volts, and the third voltage level is equal to 0.6 volts, 0.75 volts, or 1 volt.

12. A memory system, comprising:
one or more controllers;
one or more memory devices coupled with at least one of the one or more controllers;
a first voltage source coupled with the one or more memory devices, the first voltage source configured to power one or more first components of the one or more memory devices at a first voltage level;
a power supply coupled with the first voltage source;
a second voltage source coupled with the one or more memory devices, the second voltage source configured to power one or more second components of the one or more memory devices at a second voltage level; and
a third voltage source coupled with the one or more controllers and the power supply, the third voltage source configured to power one or more third components of the one or more controllers at a third voltage level, wherein the third voltage level is less than the first voltage level and the second voltage level.

13. The memory system of claim 12, wherein the third voltage source is coupled with a first voltage regulator of the one or more controllers, the first voltage regulator configured to output a signal to the one or more memory devices to power one or more fourth components of the one or more memory devices at a fourth voltage level that is less than the third voltage level.

14. The memory system of claim 12, wherein the third voltage source is coupled with a second voltage regulator of the one or more controllers, the second voltage regulator configured to output a signal to the one or more controllers to power the one or more third components of the one or more controllers at a fourth voltage level that is less than the third voltage level.

15. The memory system of claim 12, wherein the second voltage source is coupled with a first voltage regulator of the one or more controllers, the first voltage regulator configured to output a signal to the one or more memory devices to power one or more fourth components of the one or more memory devices at a fourth voltage that is less than the third voltage level.

16. The memory system of claim 12, wherein the third voltage source is further coupled with the one or more memory devices and further configured to power one or more fourth components of the one or more memory devices at the third voltage level.

17. The memory system of claim 12, wherein the second voltage source is further coupled with a first voltage regulator of the one or more controllers, the first voltage regulator configured to output a signal to the one or more controllers to power one or more fourth components of the one or more controllers at a fourth voltage that is less than or equal to the third voltage level.

18. The memory system of claim 17, wherein the one or more fourth components of the one or more controllers comprise a processing unit of the one or more controllers.

19. The memory system of claim 12, wherein the one or more third components of the one or more controllers comprise a processing unit of the one or more controllers.

20. The memory system of claim 12, wherein the one or more second components of the one or more memory devices comprise a data path associated with the one or more memory devices.

21. The memory system of claim 12, wherein the second voltage level is less than the first voltage level.

22. The memory system of claim 12, wherein the first voltage level is equal to 2.5 volts, the second voltage level is equal to 1.2 volts, and the third voltage level is equal to 0.6 volts, 0.75 volts, or 1 volt.

23. A memory system, comprising:
one or more controllers;
one or more memory devices coupled with at least one of the one or more controllers;
a first voltage source coupled with the one or more memory devices, the first voltage source configured to power one or more first components of the one or more memory devices at a first voltage level; and
a second voltage source coupled with a first voltage regulator of the one or more controllers, a second voltage regulator of the one or more controllers, and the one or more memory devices, the second voltage source configured to power one or more second components of the one or more controllers and one or more third components of the one or more memory devices at a second voltage level, wherein the second voltage level is less than the first voltage level.

24. The memory system of claim 23, wherein the first voltage regulator is configured to output a signal to the one or more controllers to power the one or more second components of the one or more controllers at a third voltage level that is less than the second voltage level.

25. The memory system of claim 23, wherein the second voltage regulator is configured to output a signal to the one or more memory devices to power one or more fourth components of the one or more memory devices at a third voltage level that is less than the second voltage level.
